(19) United States
(12) Patent Application Publication
(10) Pub. No.: US 2012/0134195 A1
(43) Pub. Date: May 31, 2012

(54) Memory Device and Manufacturing Method Thereof

(76) Inventor: Jai-Hoon Sim, Gyeonggi-do (KR)

(21) Appl. No.: 13/298,196

(22) Filed: Nov. 16, 2011

(30) Foreign Application Priority Data
Nov. 29, 2010 (KR) 10-2010-0119500

(51) Int. Cl. G11C 5/06; H01L 21/8239

(52) U.S. Cl. 365/72; 438/156; 257/E21.645

(57) ABSTRACT

The present invention relates to a memory device having 4F2 size cells and a method for fabricating the same. The memory device comprises plural word lines arranged parallel to each other in one direction, plural bit lines arranged parallel to each other, and plural memory cells having a transistor that fills a groove between two adjoining memory cells in a direction of the bit lines. A side wall between the two adjoining memory cells is simultaneously covered by an insulating film formed between the gate terminal and the two memory cells. The gate terminal is connected electrically to a word line, drain terminals of two adjoining memory cells are connected electrically to a bit line, and the gate and drain terminals are alternately arranged. One of the plural memory cells is buried in the substrate, and is electrically connected with a substrate or a well formed in the substrate.

### CLAIM TO FOREIGN PRIORITY

This application claims priority to the filing date of Korean Patent Application No. 10-2010-0119500, filed Nov. 29, 2010, the contents of all of which are hereby incorporated by reference.

### FIELD OF THE INVENTION

The present invention relates to a memory device having 4F2 size cells and a manufacturing method thereof.

### BACKGROUND OF THE INVENTION

Generally, RAM (Random Access Memory) refers to a computer memory unit which is read and written freely, and is used mainly as a unit on which data is stored temporarily. DRAM (Dynamic Random Access Memory) is a kind of RAM and stored information is diminished as time passes and thus the diminished information has to be reproduced periodically. Meanwhile, DRAM is simple structure and integrated easily and thus is used as a high-capacity temporary storage device.

DRAM comprises a plurality of word lines, a plurality of bit lines, and a plurality of memory cells which are electrically connected between the word lines and bit lines and have transistor and capacitor wherein the capacity of DRAM is determined depending on the number of memory cells within DRAM chip.

Currently, DRAM has a memory cell size of 8F2 (8F squared). Here, a minimal processing size (F) of DRAM corresponds to widths of word lines and bit lines and an interval between the word line and bit line. An area occupied by one memory cell is 8F2 (4F×2F). In order to fabricate high-capacity DRAM, the minimal process size (F) has to become smaller or the memory cell has to be designed or arranged more intensively under a predetermined minimal process size (F). As the minimal process size (F) becomes smaller to meet a physical limitation, memory cell size tends to become smaller.

In order to arrange memory cells more intensively, DRAMs having DRAM cell sizes of 6F2 (3F×2F) and 4F2 (2F×2F) have been proposed. Among them DRAM having a memory cell size of 4F2 includes most intensively arranged DRAM cell and provides high-capacity DRAM.

FIG. 1 shows cell arrangement in a 4F2 memory cell DRAM. Referring to FIG. 1, memory cells 10 are placed at intersectional points of word lines WL0-WL3 and bit lines BL0-BL3, respectively.

A proposed configuration example of a memory cell 10 is shown in FIG. 2. Referring to FIG. 2, a bit line BL is located on a lower side of the memory cell and a word line WL intersects the bit line BL and is placed thereabove. Meanwhile, a drain 11 is placed between the word line WL and bit line BL and further a channel 12 and a gate insulating member 13 surrounding the channel 12 are formed on a portion of the word line WL disposed above-part of the drain 11. Additionally, a source 14 is placed above the channel 12 and the gate insulating member 13. A capacitor 15 is placed above the source 14 and the upper part of the capacitor 15 is grounded. Here, the drain 11, gate insulating member 13, source 14 form one transistor and the transistor and the capacitor 15 form one memory cell 10, and thus the memory cell 10 is formed vertically at an intersectional point of the bit line BL and word line WL.

However, DRAM of the 4F2 memory cells has the following problems: (1) since the channel 12 and the gate insulating member 13 are formed within the word line WL having a width of the minimal processing size F, a fabrication process of DRAM is very difficult and intricate. In addition, resistance and capacitance of the word line WL are increased abruptly by the channel 12 and the gate insulating member 13 and thus an application thereof is difficult and (2) the drain 11 formed of N+ implanted silicon is formed vertically above the bit line BL which is made of metal, and resistance of the drain is larger than that of the bit line BL. Additionally, in order to form the memory cell 10 including the drain 11 on the bit line BL formed of metal a process of Epi-Growth or poly-silicon crystallization is necessary and in this case, leakage control of the memory cell 10 is difficult. As a result, DRAM of 4F2 memory cell has not been widely used regardless of its high integration degree.

### SUMMARY OF THE INVENTION

The present invention has been proposed to solve the aforementioned drawbacks of the prior art, and one object of the present invention relates to providing a memory device and a manufacturing method thereof in which memory of 4F2 memory cell can be fabricated based on metal wiring technology of the same word line and bit line as the prior DRAM of 8F2 or 6F2 memory cell.

In order to achieve the aforementioned objects, the present invention provides a memory device comprising: plural word lines arranged parallel to each other in one direction; plural bit lines arranged parallel to each other; and plural memory cells in which the gate terminal of the transistor fills an associated one of the grooves between two adjoining memory cells in a direction of the bit line, a side wall between the two adjoining memory cells is simultaneously covered by a insulating film formed between the gate terminal and the two memory cells, the gate terminal is electrically connected to the word line, and a drain terminal of the transistor is electrically connected to the bit line, wherein the gate terminal connected to one word line is arranged alternately to the gate terminal connected to adjoining word line, and the drain terminal connected to one bit line is arranged alternately to the drain terminal connected to adjoining bit line, the drain terminals of the transistors of two adjoining memory cells in a direction of word line are electrically connected to each other with respect to one bit line, at least one of the plural memory cell further includes the contact portion to be electrically connected with a semiconductor substrate or a well formed in the semiconductor substrate, and buried in the semiconductor substrate.

A distance between the gate terminals in the direction of bit line or word line may be larger than 1F, the F represents a minimal processing size.

The gate terminal is placed at an interval that is four times a bit line width and the drain terminal may be placed at an interval that is four times a word line width.

The bit line may be formed to be buried within a semiconductor substrate.

The drain terminal is spaced vertically from the source terminal and at least a part thereof may be overlapped in a plane.

The plurality of memory cells has a capacitor electrically connected to the transistor and a source terminal of the transistor.

Further, a memory device of the present invention includes plural word lines arranged parallel to each other in one direction; plural bit lines arranged parallel to each other; and plural memory cells in which the gate terminal of transistor fills associated one of grooves between two adjoining memory cells in a direction of bit line, a side wall between the two adjoining memory cells is simultaneously covered by an insulating film formed between the gate terminal and the two memory cells, the gate terminal is electrically connected to the word line, and a drain terminal of the transistor is electrically connected to the bit line, wherein the gate terminal connected to one word line is arranged alternately to the gate terminal connected to adjoining word line, and the drain terminal connected to one bit line is arranged alternately to the drain terminal connected to adjoining bit line, the drain terminals of the transistors of two adjoining memory cells in a direction of word line are electrically connected to each other with respect to one bit line, At least one of the plural memory cells further includes a contact portion to be electrically connected with a semiconductor substrate or a well formed in the semiconductor substrate, and buried in the semiconductor substrate.

A variable resistance memory device may be disposed between the bit line and the drain terminal, and the variable resistance memory device can have at least two resistance values.

Further, a method for fabricating a memory device according to the invention comprises steps of: forming plural drains at a predetermined depth of the silicon substrate in a continuous manner as a diamond shape; forming a contact portion between regions formed with two adjoining bit lines to each other among the regions formed with plural bit lines on the silicon substrate; forming the plural bit lines which are buried within the silicon substrate and extended vertically on the drain; forming plural sources on laterally adjoining region to the drain of the silicon substrate; forming plural gate at a predetermined depth of a vertically adjoining region to the source of the silicon substrate; and forming plural word lines extending laterally on the gate, wherein the gate fills associated one of grooves between two adjoining memory cells in a direction of bit line, a side wall between the two adjoining memory cells is simultaneously covered by an insulating film formed between the gate and the two memory cells, the gate is electrically connected to the two adjoining memory cells in a direction of bit line to allow two adjoining memory cells in a direction of bit line to share the gate connected to the one word line.

A distance between the gates in the direction of bit line or word line may be larger than 1F, the F represents a minimal processing size.

The step of forming the drain includes forming plural grooves on a semiconductor substrate, which are arranged in a continuous manner as a diamond shape wherein a lateral length is four times a bit line width and a vertical length is four times a word line width; forming a conductive film doped with impurities within the groove; and performing a heat treatment process for the impurities to be diffused.

The step of forming the gate includes steps of: forming a groove on a vertically adjoining region to the source of the silicon substrate; forming a gate insulating film on inside wall of the groove; and filling an inside of the gate insulating film with a conductive material.

The method for fabricating the memory device further includes step of: forming plural capacitors on the source.

The method for fabricating a memory device according to the invention includes a steps of forming plural drains at a predetermined depth of the silicon substrate in a continuous manner as a diamond shape; forming plural bit lines which are buried within the silicon substrate and extended vertically on the drain; forming plural sources on laterally adjoining region to the drain of the silicon substrate; forming plural gate at a predetermined depth of a vertically adjoining region to the source of the silicon substrate; and forming plural word lines extending laterally on the gate, wherein the gate fills associated one of grooves between two adjoining memory cells in a direction of bit line, a side wall between the two adjoining memory cells is simultaneously covered by an insulating film formed between the gate and the two memory cells, the gate is electrically connected to the two adjoining memory cells in a direction of bit line to allow two adjoining memory cells in a direction of bit line to share the gate connected to the one word line.

A distance between the gates in the direction of bit line or word line may be larger than 1F, where F represents a minimal processing size.

The method for fabricating the memory device further includes forming a contact portion between regions formed with two adjoining bit lines to each other among the regions formed with the plural bit lines on the silicon substrate.

According to the embodiments of the present invention, a drain and a gate of a memory cell are formed lower than a word line and a bit line and thus the memory cell can be formed of silicon substrate and word line and bit line of metal material can be formed thereover. Additionally, since minute configurations are not needed within the word line and bit line, the resistance and capacitance of the word line and bit line are not increased. Accordingly, according to the present invention highly integrated DRAM cells can be manufactured having the aforementioned advantages.

Further, the memory device of the invention includes a contact portion that is electrically connected with a semiconductor substrate, or a well formed in the semiconductor substrate, thereby solving the problem of a floating body caused by electric insulation between the memory device and the semiconductor substrate.

### BRIEF DESCRIPTION OF THE DRAWINGS

FIG. 1 shows a memory cell arrangement of 4F2 memory cell DRAM according to the prior art;

FIG. 2 shows a memory cell configuration of 4F2 memory cell DRAM according to the prior art;

FIG. 3 shows a memory cell arrangement of 4F2 memory cell DRAM according to the present invention;

FIG. 4 shows a circuit of 4F2 memory cell DRAM according to the present invention;

FIG. 5 shows schematically a fabricated 4F2 memory cell DRAM according to one embodiment of the present invention;

FIGS. 6 and 7 show sectionally 4F2 memory cell DRAM according to one embodiment of the present invention;

FIGS. 8-17 show manufacturing methods of 4F2 memory cell DRAM according to the present invention;

FIG. 18 schematically shows a circuit of 4F2 memory cell DRAM according to another embodiment of the present invention;

FIG. 19 is a pictorial view schematically showing 4F2 memory cell DRAM according to another embodiment of the present invention;

FIGS. 20 and 21 are cross sectional views for 4F2 memory cell DRAM according to another embodiment of the present invention; and

FIGS. 22-33 show manufacturing methods of 4F2 memory cell DRAM according to another embodiment of the present invention.

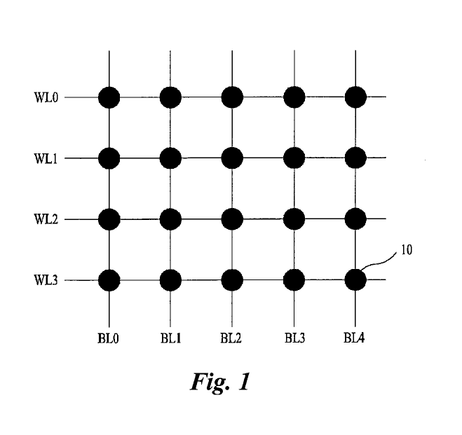

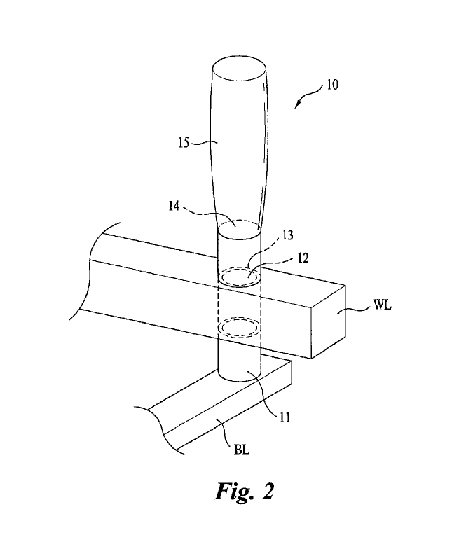

### DETAILED DESCRIPTION OF THE DRAWINGS

The preferred embodiments of a memory device according to the present invention will be described in detail referring to the accompanying drawings.

Further, to ease the description, the DRAM device applied with the invention will be described. However, the invention is not limited thereto, and is applied to another memory device such as SRAM, PRAM, MRAM, STT (Spin Transfer Torque)-RAM, FRAM (Ferroelectric RAM), RAM (Resistive RAM), etc.

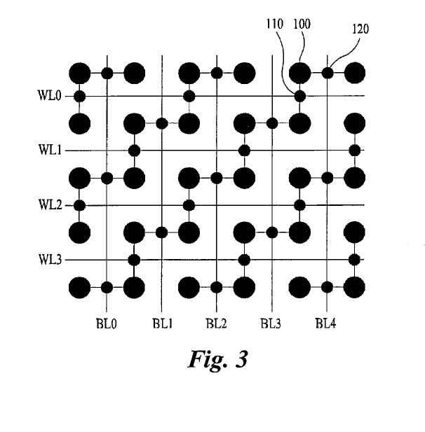

Then, the memory device and manufacturing methods of the same according to an embodiment of the invention will be described in detail with reference to FIGS. 3-17.

FIG. 3 shows schematically a memory cell arrangement for DRAM according to the present invention. Referring to FIG. 3, with respect to plural word lines WL0-WL3, their widths and intervals are preferably extended laterally as a minimal process size (F), and with respect to plural bit lines BL0-BL3 their widths and intervals are preferably extended vertically as a minimal process size (F), and further memory cells 100 are placed on parts (respective vertical and lateral lengths correspond to the minimal process size (F)) which are not occupied by the word lines WL0-WL3 and the bit lines BL0-BL3, respectively. The number of the memory cells 100 are calculated through multiplying numbers of the word lines by numbers of the bit lines, and further area occupied by respective DRAM cell becomes 4F2 (2F×2F).

One end 110 (referring to as a gate terminal which is described below) of a memory cell 100 is connected electrically to the word line and the other end 120 (referring to as a drain terminal which is described below) of the memory cell 100 is connected electrically to the bit line. One end 110 is arranged at an interval four times a minimal process size (4F) along one word line and the other end 120 of the memory cell is arranged at an interval four times a minimal process size (4F) along one bit line. One end 110 of the memory cell arranged along one word line is placed alternately on one end 110 of the memory cell arranged along adjoining word line and thus one ends 110 of the memory cell are arranged in a diamond shape having vertical and lateral lengths of four times a minimal process size (4F). In the same manner, the other end 120 of the memory cell arranged along one bit line is placed alternately on the other end 120 of the memory cell arranged along adjoining bit line and thus the other ends of the memory cell are arranged in a diamond shape having vertical and lateral lengths of four times a minimal process size (4F).

One end 110 of two adjoining memory cells 100 is connected electrically with respect to one word line and the other end 120 of two adjoining memory cells 100 is connected electrically with respect to one bit line, and thus the memory cells are shown to be connected in a stepwise in FIG. 3.

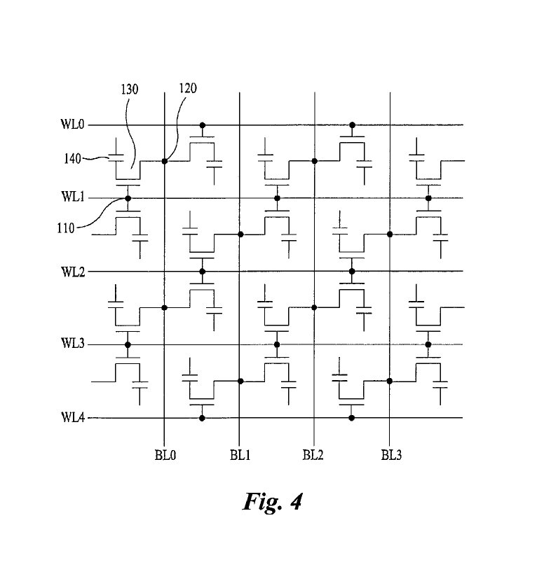

In more detail, referring to the circuit shown in FIG. 4, the memory cell 100 includes a transistor 130 and a capacitor 140. A source terminal of the transistor 130 is connected electrically to one end of the capacitor 140 and a gate terminal (referring to as one end 110 of the memory cell 100) is connected electrically to the word line WL1, and a drain terminal (referring to as the other end of the memory cell 120) is connected electrically to the bit line BL0. The gate terminal 110 of the transistor 130 is formed of gate oxide and the drain terminal 120 of the transistor 130 is formed of N+ implanted silicon. One end of the capacitor 140 is connected electrically to the source terminal of the transistor 130 and the other end of the capacitor 140 is grounded (not shown).

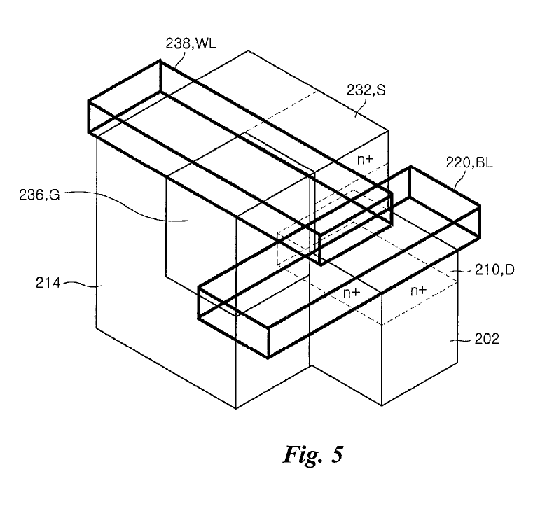

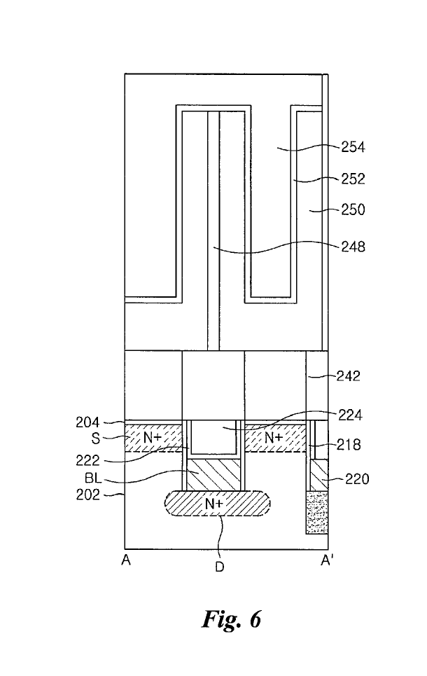

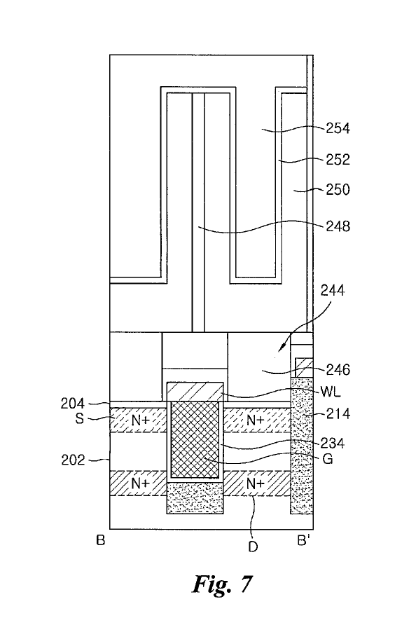

A more detailed configuration of a DRAM device according to one embodiment of the present invention is described referring to FIGS. 5-7. In FIG. 5, an upper configuration of the word line and bit line is omitted for clarity. FIG. 6 is a sectional view taken along a line parallel to the word line WL in FIG. 5 and FIG. 7 is a sectional view taken along a line parallel to the bit line BL in FIG. 5.

Referring to FIGS. 5-7, a DRAM device according to one embodiment of the present invention includes a bit line BL which is buried within a semiconductor substrate 202 and formed in one direction, a word line WL which is formed on the semiconductor substrate 202 and in the direction orthogonal to the bit line BL, and a memory cell which is connected electrically to the bit line BL and the word line WL.

The bit line BL is formed to be buried within the semiconductor substrate 202. The bit line BL is formed of conductive material such as poly-silicon, metal or metal alloy, etc. A drain D is formed on the semiconductor substrate 202 below the bit line BL. The drain D is diffused horizontally toward a lower side of the source S and the drain D is spaced vertically from the source S and at least one part of them is overlapped on a plane. As a result, a channel is formed between the drain D and the source S. One memory cell 100 shares the drain D with another adjoining memory cell, placing the bit line BL therebetween.

The word line WL is formed on the semiconductor substrate 202. The word line WL is formed of conductive material such as poly-silicon, metal or metal alloy, etc. A gate G is formed on the semiconductor substrate 202 below the word line WL. The memory cell 100 shares the gate G with other adjoining memory cell, placing the word line WL therebetween.

That is, the transistor 130 of the memory cell 100 includes the source S, the drain D and the gate G, as shown in FIGS. 5-7 wherein the drain D is shared with an adjoining memory cell at one side and is connected electrically to the bit line BL and further the gate G is shared with an adjoining memory cell at the other side and is connected electrically to the word line WL.

More detailed configuration of DRAM, including the bit line BL, the word line WL and the DRAM cell 100, will be described below.

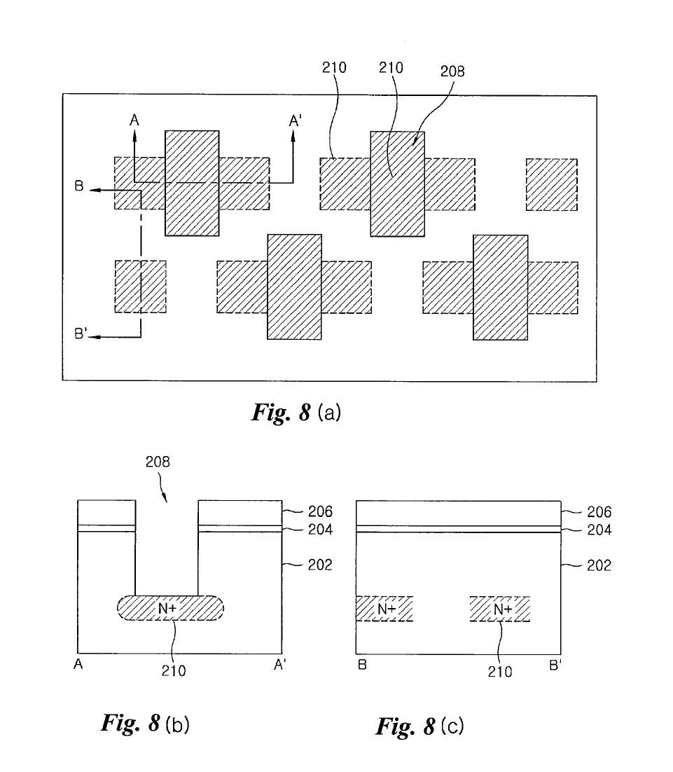

In particular, a manufacturing method of 4F2 memory cell DRAM from silicon substrate 202 according to the present invention will be described, referring to FIGS. 8-17.

FIGS. 8a-8c show a silicon substrate on which N+ implanted regions are formed. FIG. 8(a) is a plan view, FIG. 8(b) is a sectional view taken by A-A′ in FIG. 8(a), and FIG. 8(c) is a sectional view taken by B-B′ in FIG. 8(a). In the following description, this indication of figure relation will be applied in the same manner throughout.

Referring to FIGS. 8a-8c, pad oxide film 204 and pad nitride film 206 are formed on the semiconductor substrate 202. The pad oxide film 204 may be formed using oxidation process, etc., and the pad nitride film 206 may be formed using Chemical Vapor Deposition (CVD), etc. The pad oxide film 204 allows the pad nitride film 206 to be deposited easily on the semiconductor substrate 202 and the pad nitride film functions as an etching mask or a polishing stopping film in the following process.

Subsequently, the semiconductor substrate 202 is etched at a predetermined depth through a photolithography process using a predetermined mask to form a plurality of first grooves 208. The region of the first groove 208 includes a region on which the drain D is formed among the region on which the bit line BL is formed later. For example, the first groove 208 has laterally a minimal process size (1F) length and has vertically two times minimal process size (2F) length.

An N+ implantation process is performed on the semiconductor substrate 202 and a first N+ implant region 210 to which N+ is implanted is formed on bottom surface of the first groove 208. The first N+ implant region 210 functions as the drain D of the DRAM cell 100. N+ ions are diffused in a sideways direction (horizontally) using a heat treatment process after the N+ implantation process for the first implant region 210 to be diffused. Accordingly, the first N+ implant region 210 is diffused to not only a region on which bit line may be formed but also to a region on which source may be formed. The first N+ implant region 210 may be diffused not only laterally but also vertically in FIG. 8(a), however, a vertically diffused region is removed through forming a device separation film later. In FIG. 8, the lateral diffused region is the only region shown for clarity. Meanwhile, the first N+ implant region 210 may be formed such that an N+ implanted conductive or nonconductive film is formed in the first groove 208 and then N+ ion within the film is diffused to inside the semiconductor substrate 202 using a heat treatment process.

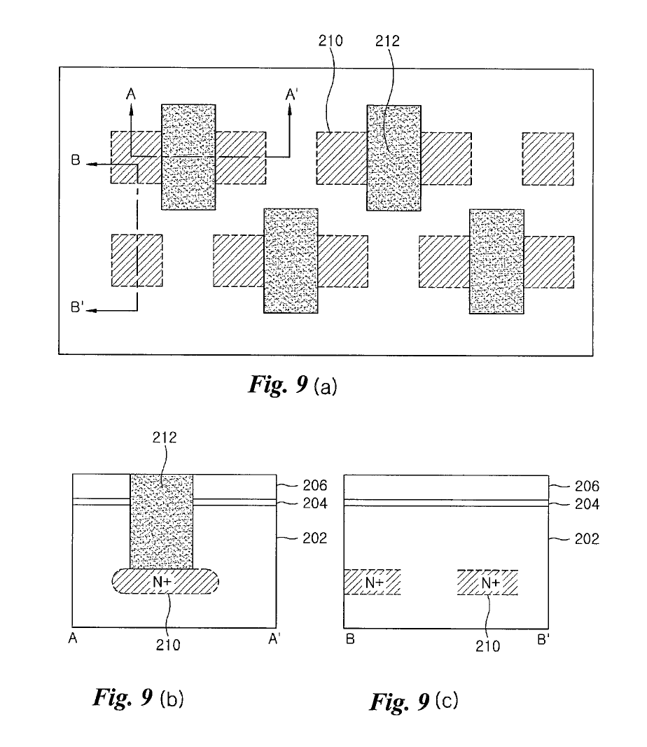

Referring to FIGS. 9a-9c, a first insulating film 212 is formed over the entire N+ implant region for the first groove 208 to be buried. The first insulating film 212 may be formed of material having a different etching selection ratio from the pad nitride film 206. Subsequently, an etching or polishing process is performed using the pad nitride film as a stopping film. Accordingly, the first insulating film 212 remains within the first groove 208.

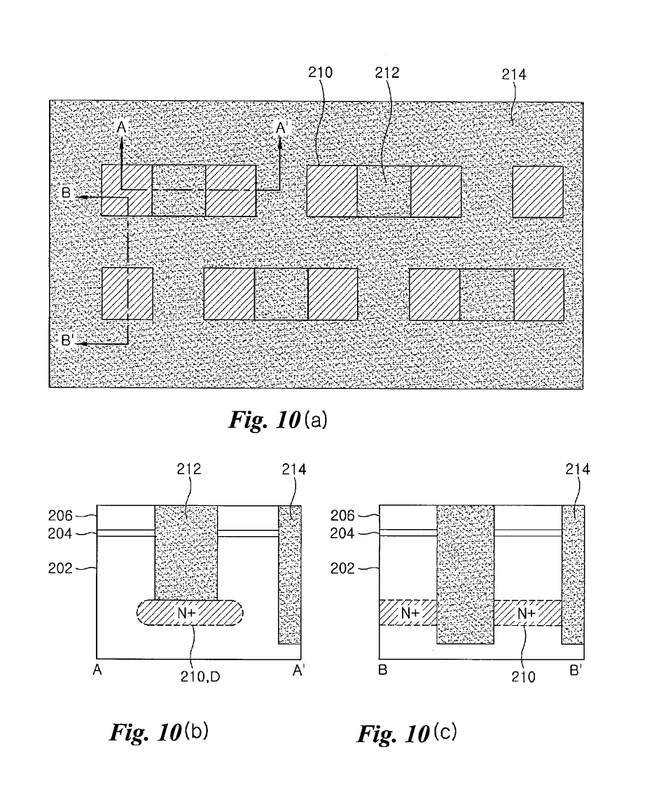

Referring to FIGS. 10a-10c, a device separation film 214 is formed by etching the semiconductor substrate 202 at a predetermined depth in regions on which a drain and source are not formed, using a device separation mask (not shown), and burying the insulating film 212. The insulating film may be formed of material having a different etching ratio from the pad nitride film 206. The device separation film 214 may be formed more deeply than the first N+ implant region 210 in order for charges not to be moved between first adjoining N+ implant regions 210.

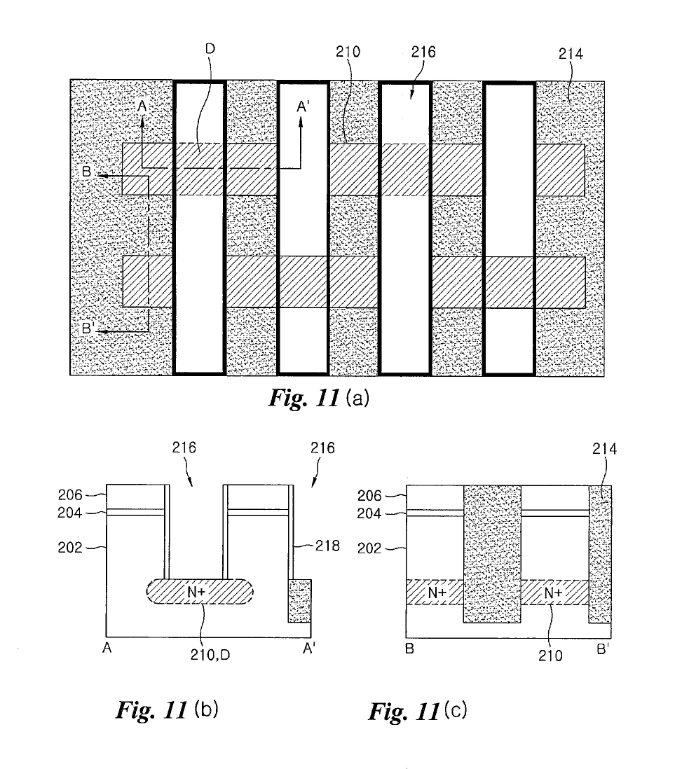

Referring to FIGS. 11a-11c, a plurality of trenches 216 is formed in a region on which a bit line is formed. The first insulating film 212 and the device separation film 214 are removed on a bit line formation region by forming the trench 216. As a result, the first N+ implant region 210 placed below the first insulating film 212 is exposed outside. Subsequently, a first side wall insulating film 218 is formed on a side wall of the trench 216. The first side wall insulating film 212 is formed such that the insulating film is formed on entire upper part including the trench 216 and then etched except for the first side wall insulating film 212.

Referring to FIGS. 8-11, the procedures are described such that the first N+ implant region 210 is formed in the first groove 208 and the device separation film 214 is formed, and the trench 216 is formed. Meanwhile, according to another embodiment of the present invention, the device separation film 214 is formed on a region except for drain formation region and source formation region, and the trench 216 is formed and then the first N+ implant region 210 may be formed. The semiconductor substrate manufactured according to the present embodiment has the same configuration as shown in FIG. 11.

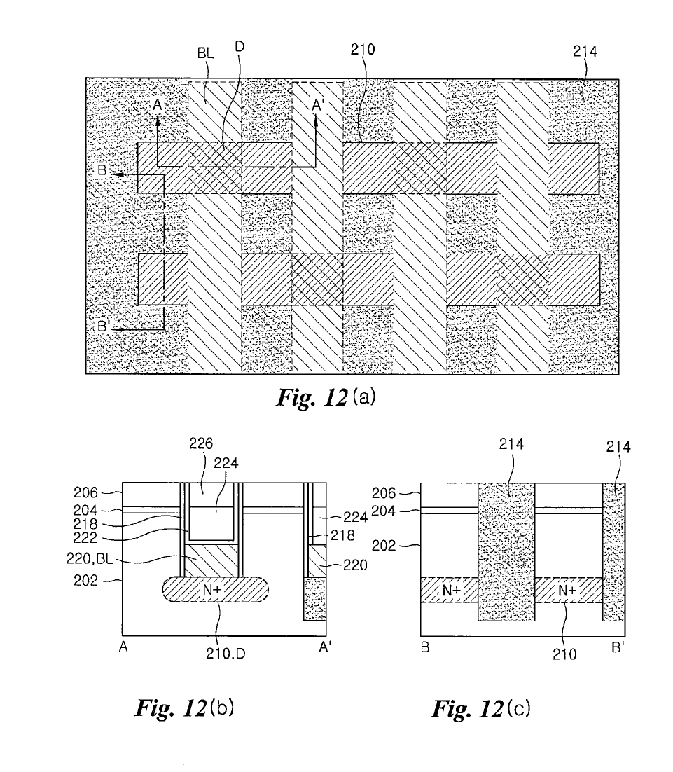

Referring to FIGS. 12a-12c, a conductive film 220 having a predetermined thickness is formed within the trench 216. The conductive film 220 functions as the bit line BL. The conductive film 220 may be formed of conductive material such as poly-silicon, metal, metal oxide, metal nitride, etc. The width and interval of the conductive film 220 preferably corresponds to the minimal process size (1F).

Subsequently, a second side wall insulating film 222 is formed over the conductive film 220 and on a side wall of the trench 216. Subsequently, a second insulating film 224 having the same height at an upper surface as an upper surface of the pad oxide film 204 is formed and then a third insulating film 226 having the same height at an upper surface as an upper surface of the nitride film 206 so that the trench 216 is buried entirely.

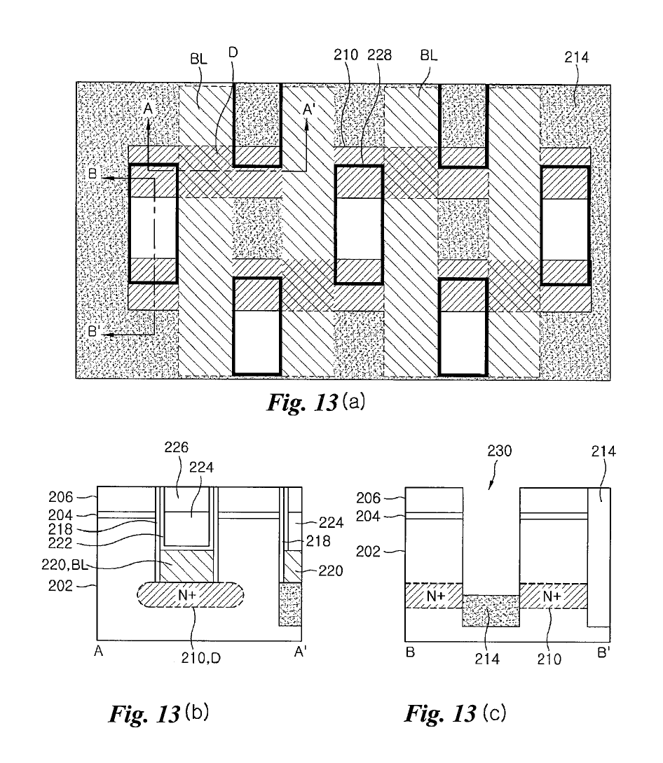

Referring to FIGS. 13a-13c, a plurality of second grooves 230 is formed on the semiconductor substrate 220 by etching at a predetermined depth the device separation film 214 placed on a gate formation region using an etching mask 228. In FIGS. 13a-13c, the etching mask 228 includes a gate formation region and a part of a source formation region, however, the device separation film 214 placed on the gate formation region is etched and the source formation region is not etched by the pad nitride film 206. The second groove 230 may be etched more deeply than the upper surface of the first implant region 210.

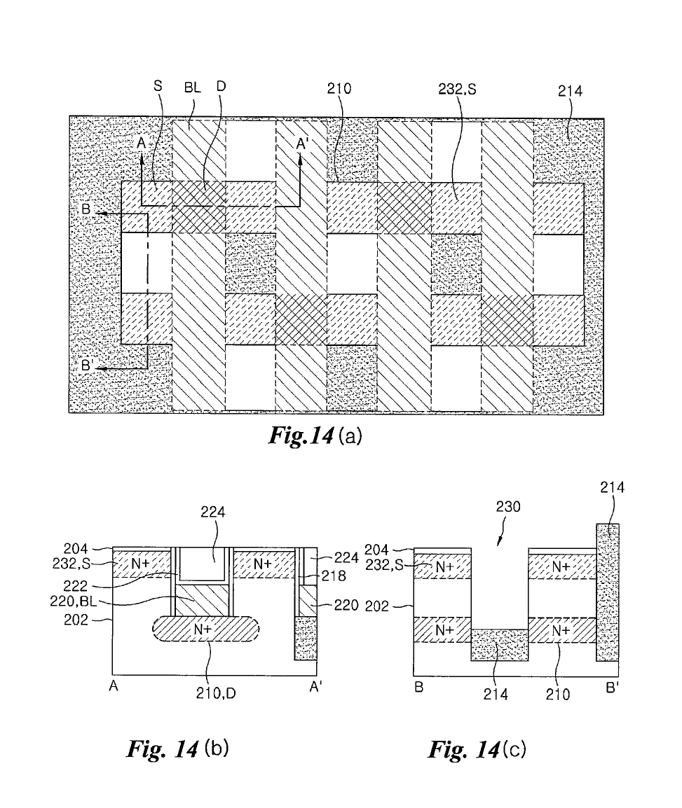

Referring to FIGS. 14a-14c, the pad nitride film 206 and the third insulating film 226 formed on the semiconductor substrate 202 are removed. Subsequently, a second N+ implant region 232 is formed on the semiconductor substrate 202 using an N+ implantation process. As shown in FIGS. 14a-14c, the second N+ implant region 232 is formed on a region that is not occupied by the bit line BL or the word line. The second N+ implant region 232 functions as a source S. The first implant region 210 functioning as the drain D is formed lower than the second N+ implant region 232 functioning as the source S and further the first N+ implant region 210 is spaced vertically from the second N+ implant region 232 and overlapped in at least a part thereof so that a channel is formed between the first N+ implant region 210 as the drain D and the second N+ implant region 232 as the source S.

Meanwhile, an ion injection process for forming a channel within the semiconductor substrate 202 may be performed before the second N+ implant region 232 is formed. The ion injection process for forming a channel may be performed using an incline ion injection process or vertical ion injection process with respect to the semiconductor substrate 202 so that impurities are injected into a side wall of the second groove 230.

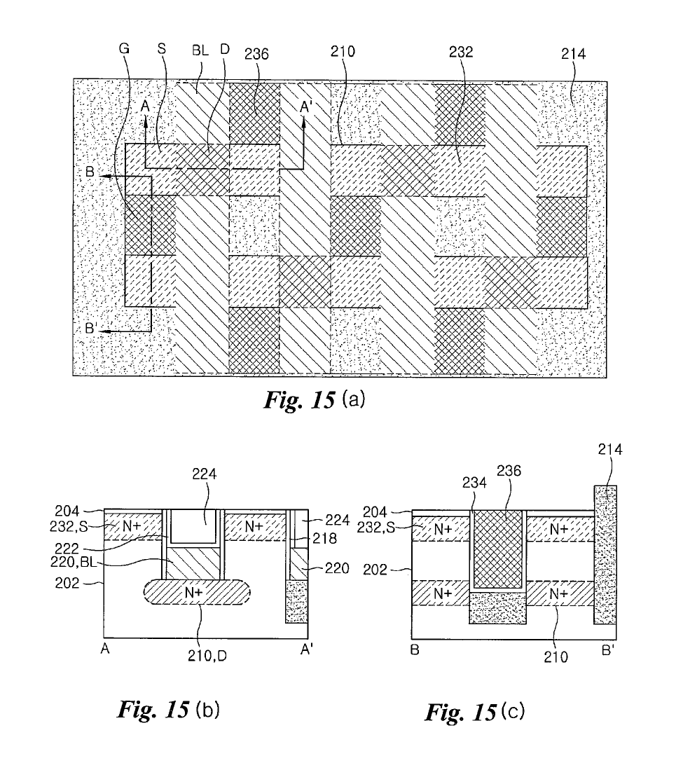

Referring to FIGS. 15a-15c, a gate insulating film 234 is formed on a side wall of the second groove 230 and then conductive film is formed for the second groove 230 to be buried to form a gate electrode 236. The gate insulating film 234 functions as a gate G and the gate electrode 236 electrically connects the gate insulating film 234 with the word line, which is formed in the following manner.

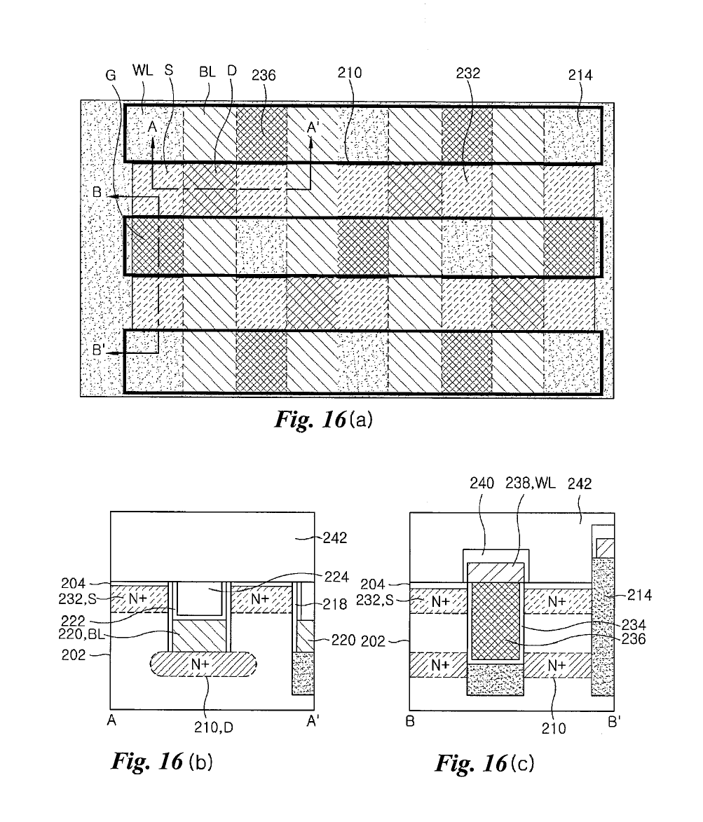

Referring to FIGS. 16a-16c, a plurality of word lines 238 extending laterally is formed on the gate electrode 236. A width and interval of the word line 238 may correspond to the minimal process size (F). A fourth insulating film 240 may be formed on an upper part and side wall of the word line 238. Additionally, an interlayer insulating film 242 is formed over entire the semiconductor substrate 202.

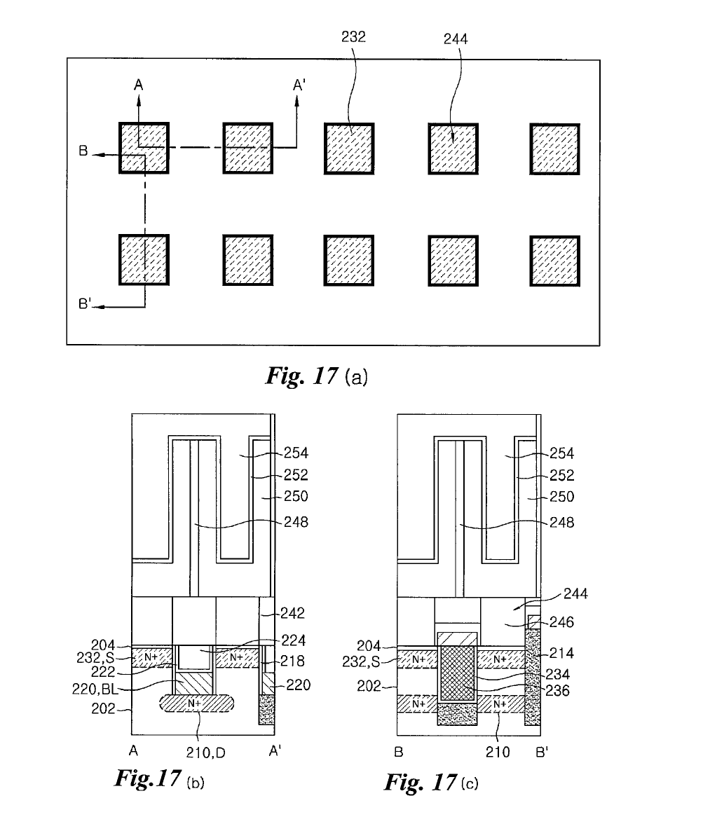

Referring to FIG. 17(a), the interlayer insulating film 242 over the second N+ implant region 232 is removed and the second N+ implant region 232 is exposed to form a contact hole 244. Referring to FIGS. 17(b) and 17(c), conductive material is filled into the contact hole 244 to form a contact plug 246. Subsequently, a sacrificial insulating film 246 is formed over the entire semiconductor substrate and then etched for the contact plug 246 to be exposed. At this time, a region wider than the contact plug 246 may be exposed. Next, a lower electrode 250 connected to the contact plug 246, a dielectric film 252 placed on the lower electrode 250, and an upper electrode 254 are formed. The lower electrode 250, the dielectric film 252 and the upper electrode 254 form one capacitor.

In FIGS. 17(b) and 17(c), the first N+ implant region 210, the second N+ implant region 232 and the gate insulating film 234 form one transistor. A source terminal of a transistor (the second N+ implant region 232) is connected electrically to a capacitor (lower electrode 250, dielectric film 252 and upper electrode 254) through the contact plug 246. A transistor and a capacitor form one DRAM cell. The memory cell 100 is arranged such that its lateral and vertical intervals each corresponds to twice minimal process size (2F) and area occupied by one memory cell 100 equals to 4F2.

A gate (a gate insulating film 234) of a transistor of two adjoining memory cells 100 based on the word line 238 as a boundary is connected electrically to the word line 238 through the gate electrode 236. The drain (the first N+ implant region 210) of a transistor of two adjoining memory cells 100 based on the bit line 220 as a boundary is shared and is connected electrically to the bit line 220.

Next, the memory device and manufacturing methods of the same according to another embodiment of the invention will be described in detail.

Since the memory device and manufacturing methods of the same according to the present embodiment are substantially the same with the memory device and manufacturing methods of the same according to previous embodiment, the different parts only will be described.

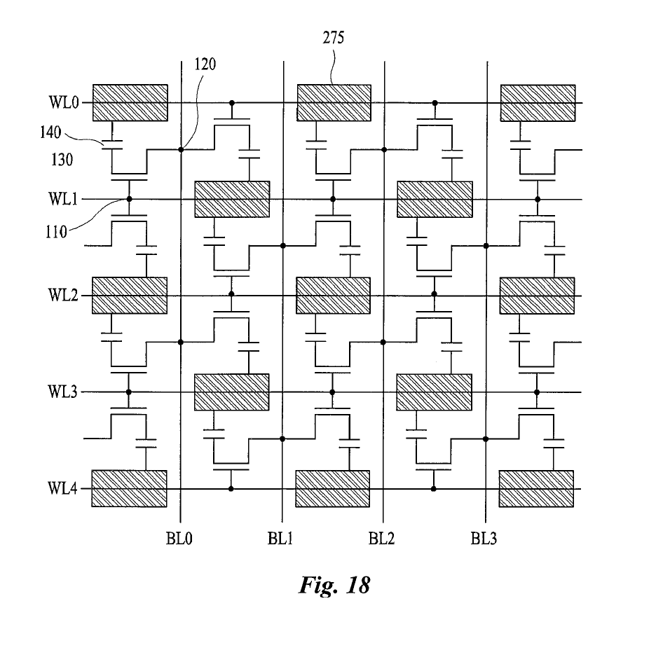

First, the memory device according to another embodiment of the present invention will be described in detail with reference to FIGS. 18-21.

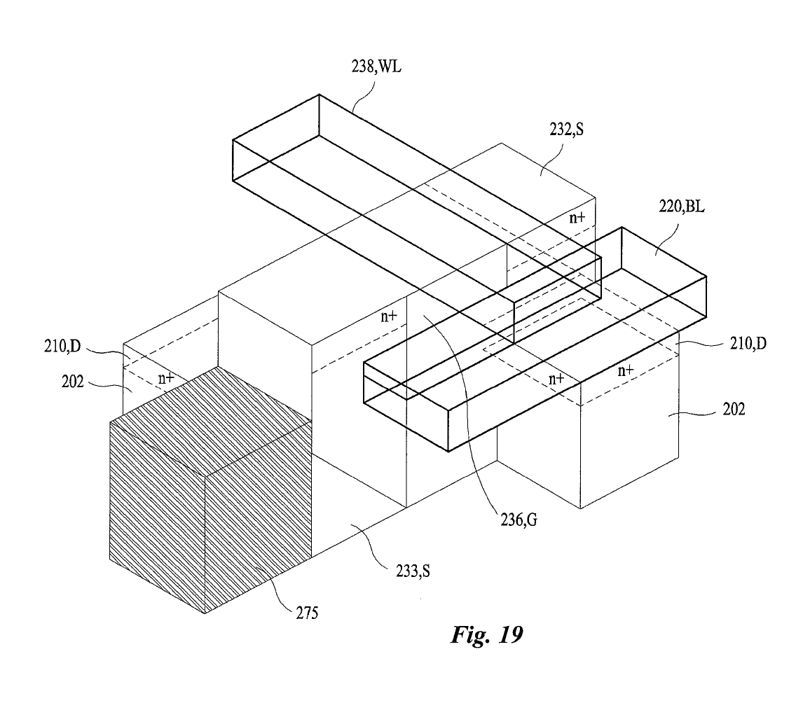

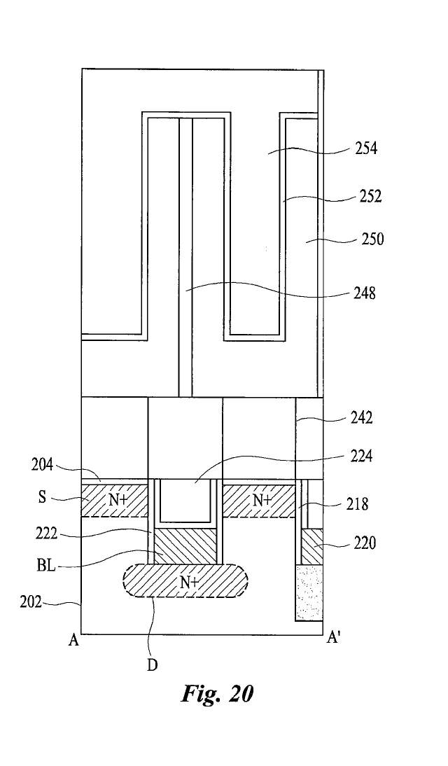

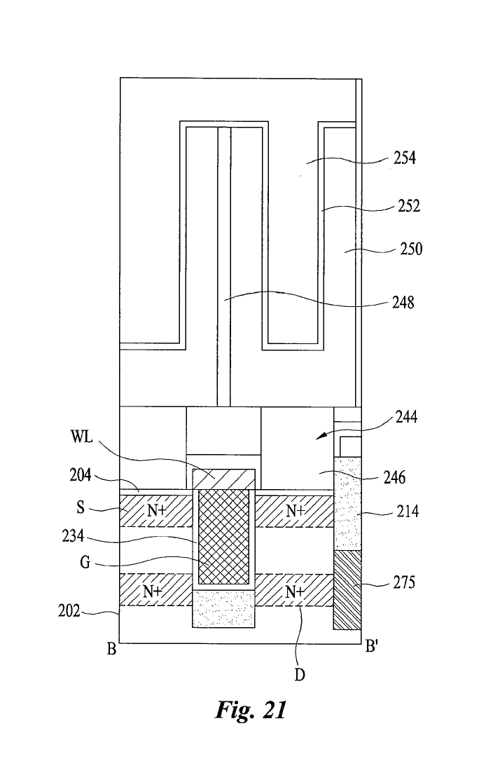

FIG. 18 schematically shows a circuit of 4F2 memory cell DRAM according to another embodiment of the present invention, FIG. 19 is a pictorial view schematically showing 4F2 memory cell DRAM according to another embodiment of the present invention, and FIGS. 20 and 21 are a cross sectional view for 4F2 memory cell DRAM according to another embodiment of the present invention.

Referring to FIG. 18, the memory device of the invention further includes a contact portion 275 to be electrically connected with a semiconductor substrate 202, or a well formed in the semiconductor substrate 202. The contact portion 275 is formed in one side of the DRAM cell 100 formed in the region between two adjacent bit lines. The contact portion 275 is formed with a conductive material such as P-type POLY, etc.

Referring to FIGS. 19 to 21, the contact portion 275 is buried at a predetermined depth within the semiconductor substrate 202 and is connected to a vertical side of one side of the memory cell 100.

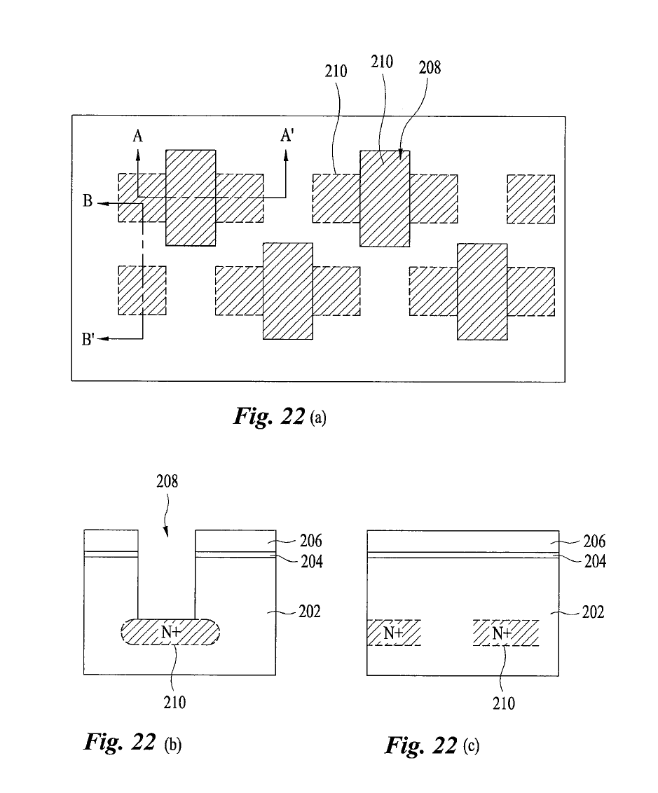

Next, the manufacturing methods of the memory device according to another embodiment of the invention will be described in detail with reference to FIGS. 22-33.

FIGS. 22-33 show manufacturing methods of 4F2 memory cell DRAM according to another embodiment of the present invention.

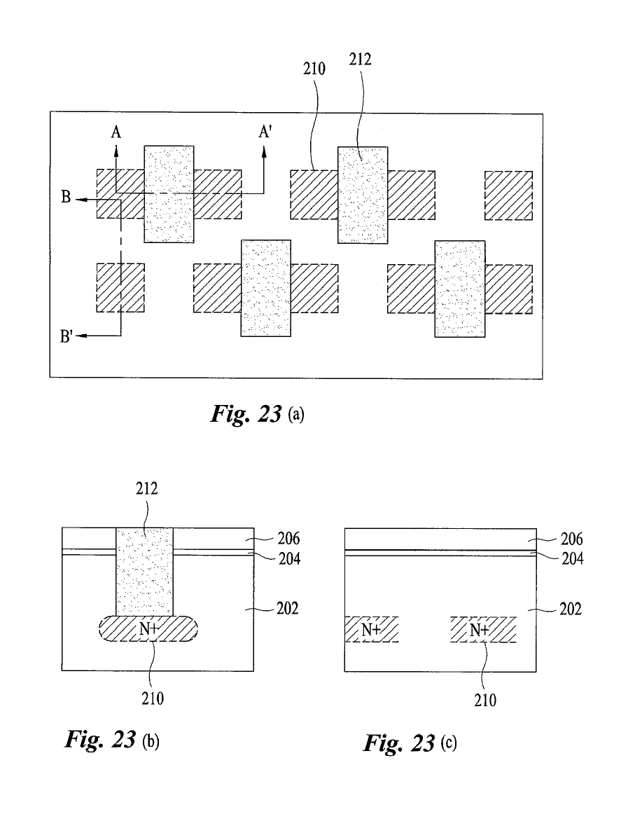

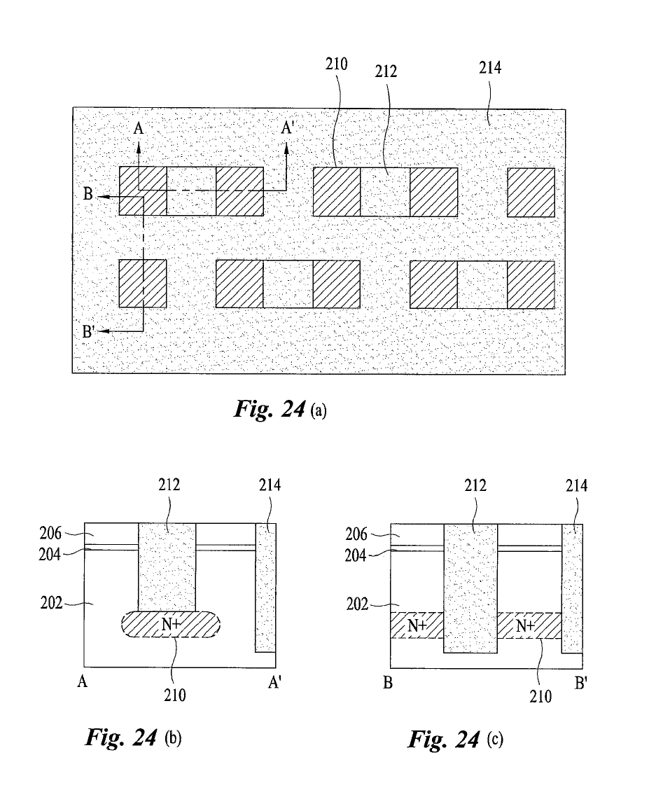

The process of forming a first N+ implant region (refer to FIG. 22), the process of forming a first insulating film (refer to FIG. 23), and the process of forming a device separation film (refer to FIG. 24) according to the present embodiment are the same as the previous embodiment, and therefore, the detailed description will be omitted.

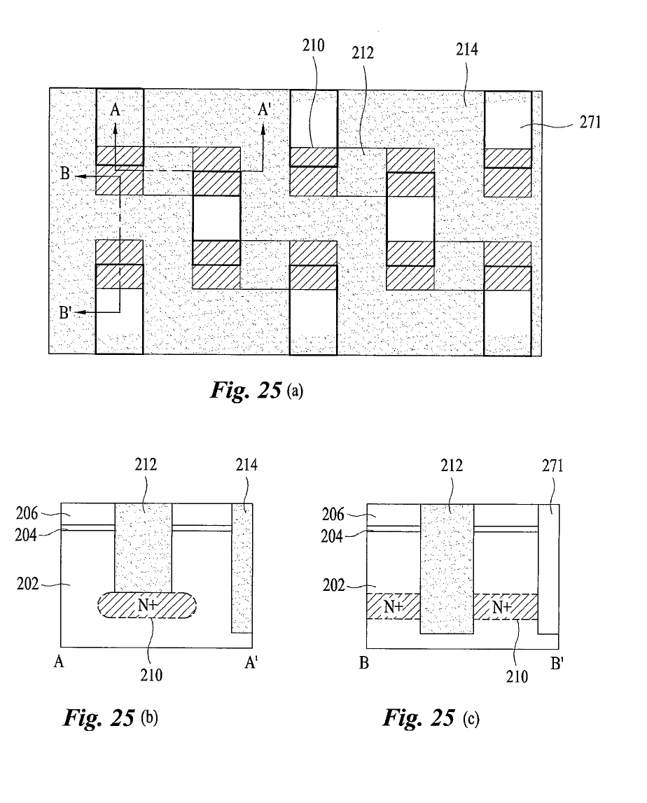

In FIG. 25, the contact region 271 formed with the contact portion 275 is etched at the determined depth. It is desirable that the depth of the contact region 271 is formed to be larger than the depth of the first N+ implant region 210.

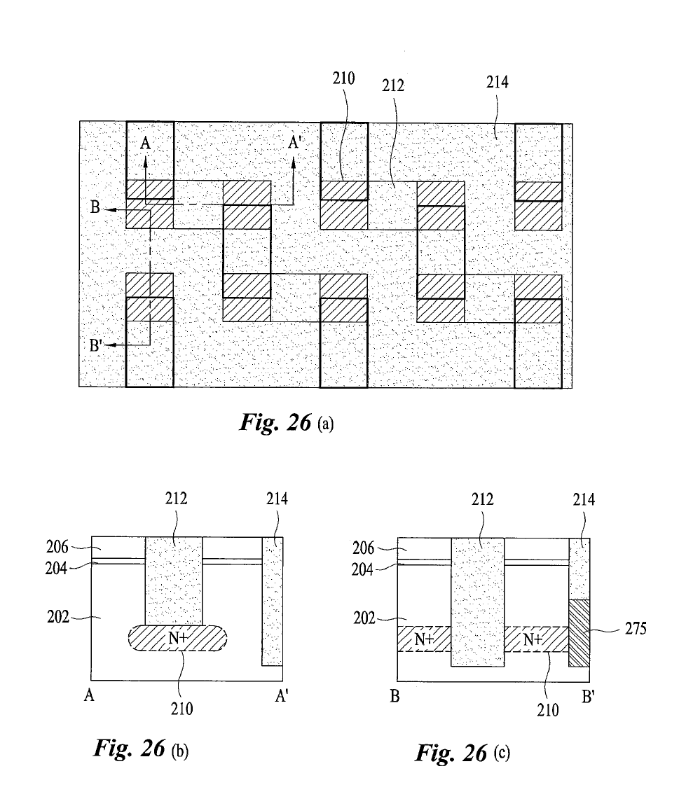

In FIG. 26, a conductive material such as P-type POLY, etc. is buried in the contact region 271 to form the contact portion 275 having a predetermined thickness. Then, the insulating film is again buried in the contact region 271 to again form the device separation film 214 on the contact portion 275.

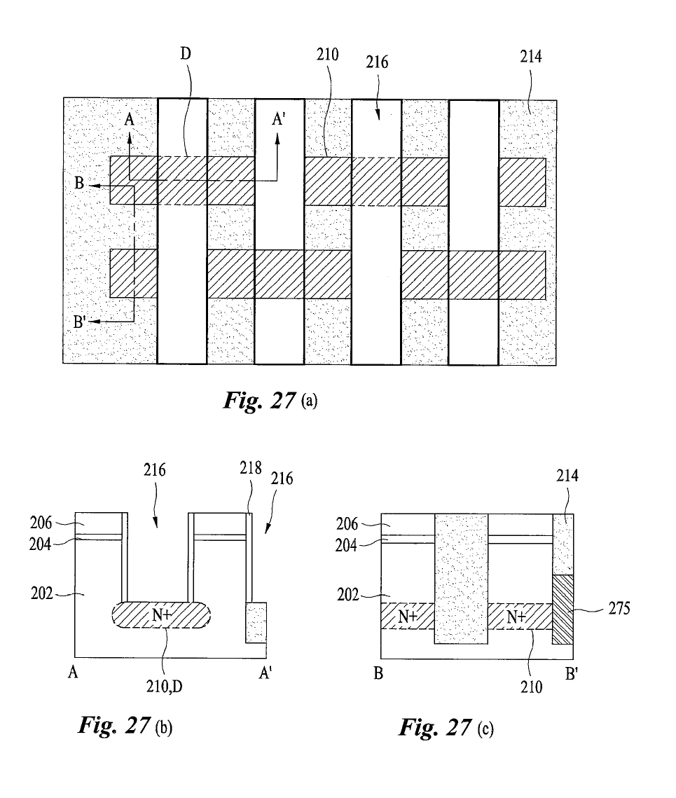

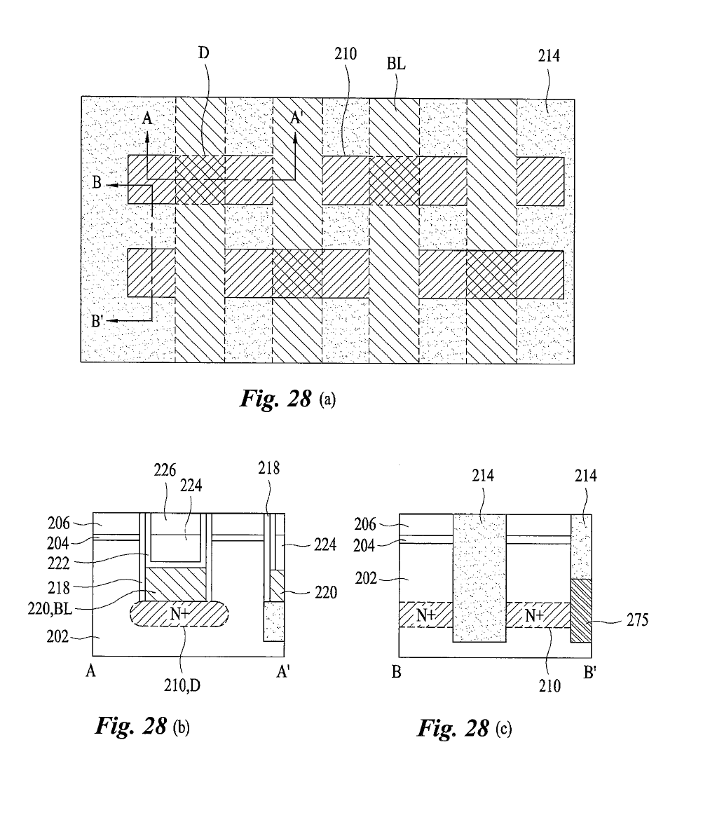

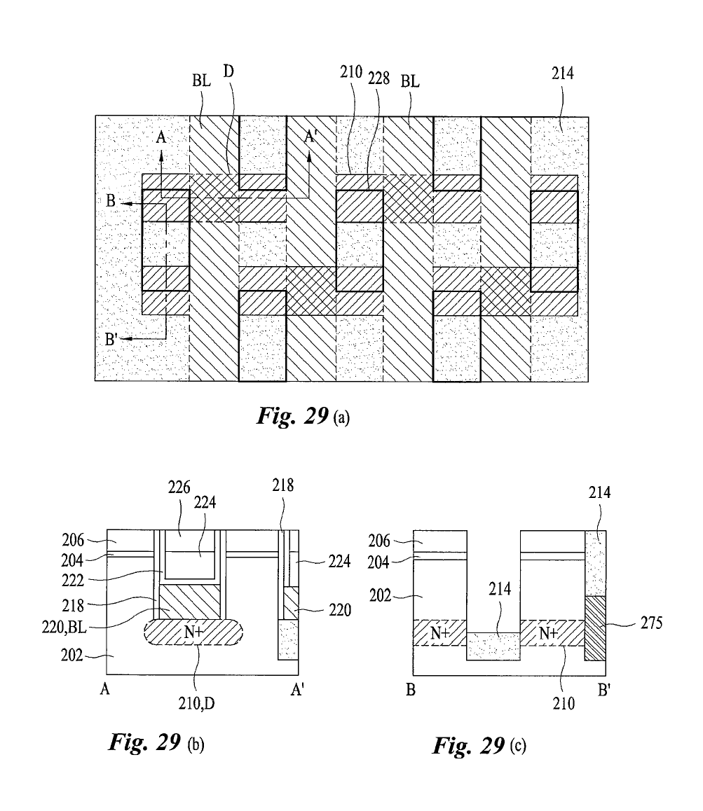

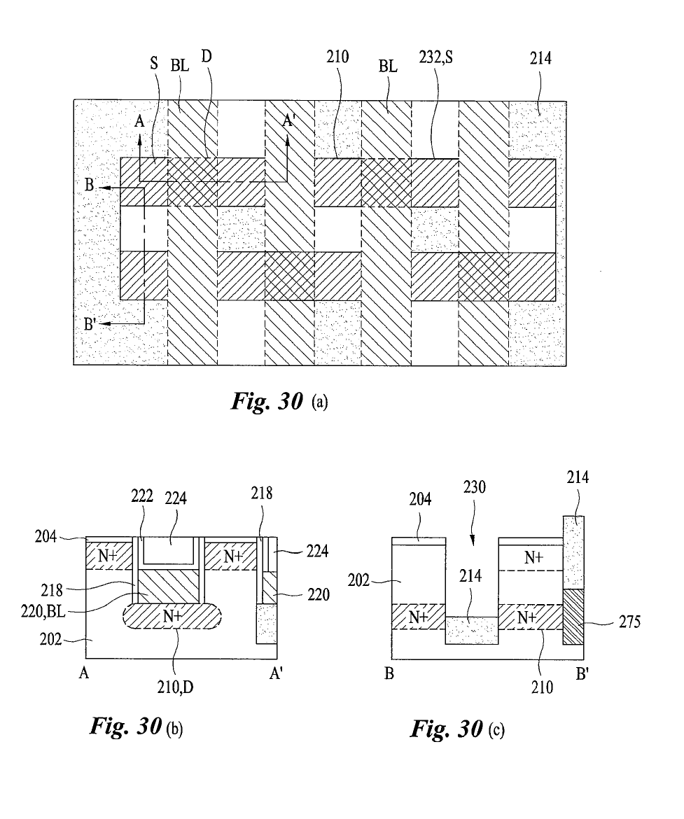

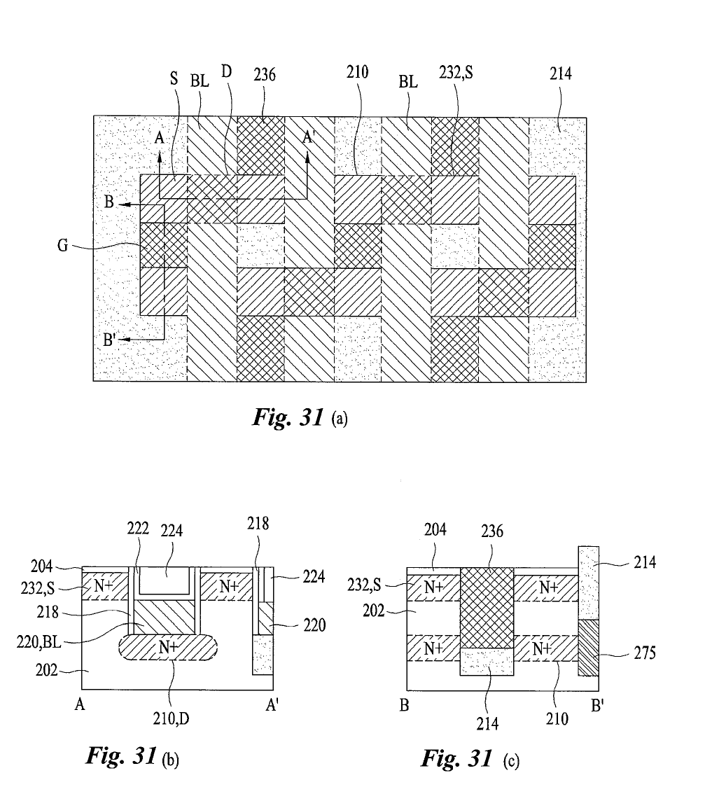

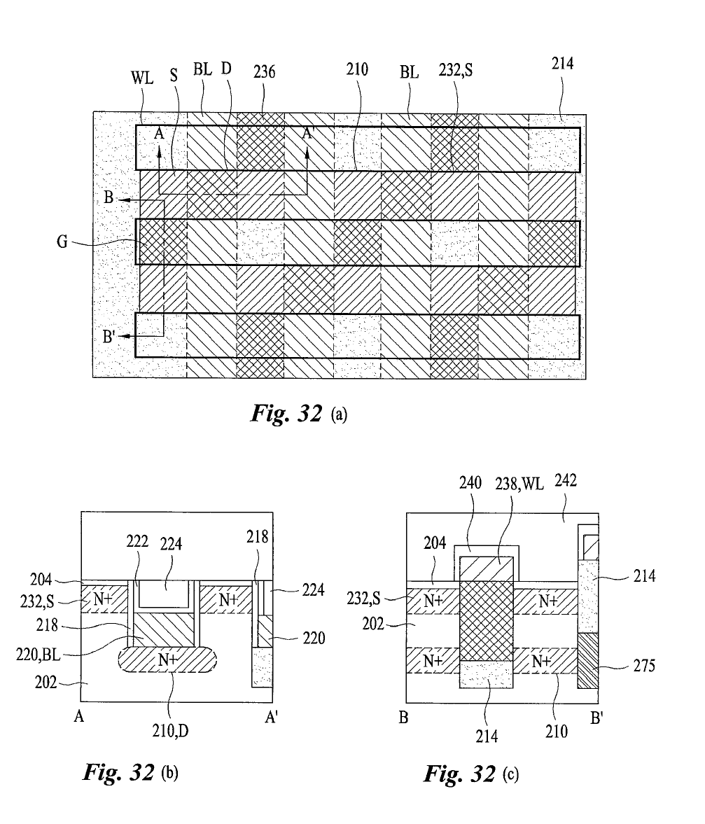

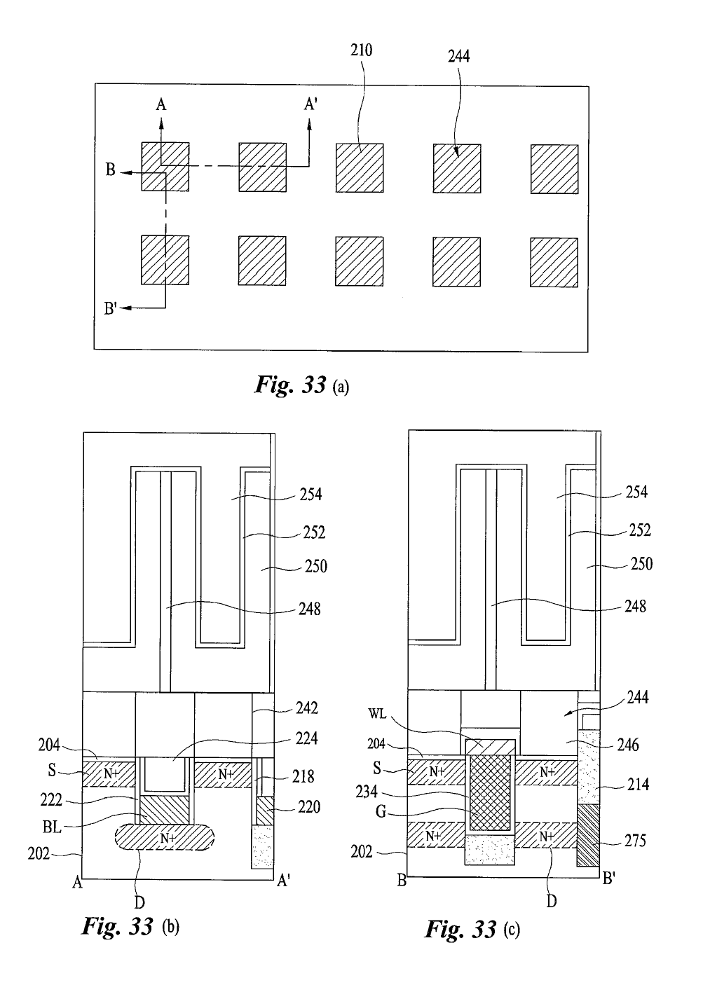

Subsequently, the process of forming a trench (refer to FIG. 27), the process of forming a bit line (refer to FIG. 28), the process of forming a second implant region (refer to FIGS. 29 and 30), the process of forming a gate insulating film and a gate electrode (refer to FIG. 31), the process of forming a word line (refer to FIG. 32) and the process of forming a contact hole (refer to FIG. 33), according to the present embodiment are the same as the previous embodiment. Therefore, the detailed description will be omitted.

On the other hand, although it is described that each of the contact portions 275 are formed on one side of a plurality of memory cells 100, other embodiments are not so limited. Therefore, the contact portions 275 may be formed in one side of the DRAM cell for at least one of the plurality of DRAM cells 100.

As explained above, the DRAM device of the invention includes the contact portion 275 that is to be electrically connected with a semiconductor substrate 202, or a well formed in the semiconductor substrate 202, thereby solving the problem of a floating body caused by electric insulation between the DRAM device and the semiconductor substrate 202.

On the other hand, for example, although it has been described previously that the invention is applied to the DRAM device, when the invention is applied to different DRAM device such as STT-RAM, MRAM (MRAM) and (RRAM), a variable resistance memory device may be disposed between the bit line and the drain terminal electrically connected thereto according to the invention. Then, the variable resistance DRAM device can have at least two electric resistance values.

While the present invention is described referring to the preferred embodiment, the present invention is not limited thereto, and thus various variations and modifications can be made without departing from a scope of the present invention as defined by the following claims.

What is claimed is:

1. A memory device comprising:
a plurality of word lines arranged parallel to each other in one direction;
a plurality of bit lines arranged parallel to each other; and
a plurality of memory cells in which a gate terminal of a transistor fills an associated one of a plurality of grooves between two adjoining memory cells in a direction of bit line, a side wall between the two adjoining memory cells is simultaneously covered by an insulating film formed between the gate terminal and the two adjoining memory cells, the gate terminal is connected electrically to the word line, and a drain terminal of the transistor is connected electrically to the bit line,
wherein the gate terminal connected to one word line is arranged alternately to the gate terminal connected to an adjoining word line, and the drain terminal connected to one bit line is arranged alternately to the drain terminal connected to an adjoining bit line,
the drain terminal of the transistor of the two adjoining memory cells in a direction of word line is electrically connected to each other with respect to one bit line,
at least one of the plural memory cell further includes the contact portion to be electrically connected with a semiconductor substrate or a well formed in the semiconductor substrate, and buried in the semiconductor substrate.

2. The memory device according to claim 1, wherein the gate terminal is placed at an interval four times the bit line width and the drain terminal is placed at an interval four times word line width.

3. The memory device according to claim 1, wherein the bit line is formed to be buried within a semiconductor substrate.

4. The memory device according to claim 1, wherein the drain terminal is spaced vertically from the source terminal and at least a part thereof is overlapped in a plane.

5. The memory device according to claim 1, wherein the memory cells have a capacitor electrically connected to the transistor and a source terminal of the transistor.

6. A memory device comprising:
word lines arranged parallel to each other in one direction;
bit lines arranged parallel to each other; and
memory cells in which the gate terminal of a transistor fills associated one of grooves between two adjoining memory cells in a direction of the bit lines, a side wall between the two adjoining memory cells is simultaneously covered by an insulating film formed between the gate terminal and the two memory cells, the gate terminal is connected electrically to the word line, and a drain terminal of the transistor is connected electrically to the bit line,
wherein the gate terminal connected to one word line is arranged alternately to the gate terminal connected to adjoining word line, and the drain terminal connected to one bit line is arranged alternately to the drain terminal connected to adjoining bit line,
the drain terminals of the transistors of two adjoining memory cells in a direction of word line are electrically connected to each other with respect to one bit line.

7. The memory device according to claim 6, wherein at least one of the memory cells further includes a contact portion to be electrically connected with a semiconductor substrate or a well formed in the semiconductor substrate, and buried in the semiconductor substrate.

8. The memory device according to claim 6, wherein a variable resistance memory device is disposed between the bit line and the drain terminal, the variable resistance memory device having at least two electric resistance values.

9. A method for fabricating a memory device on a silicon substrate comprising the steps of:
forming drains at a predetermined depth of the silicon substrate in a continuous manner as a diamond shape;
forming a contact portion between regions forming two adjoining bit lines to each other among the regions forming plural bit lines on the silicon substrate;
forming bit lines which are buried within the silicon substrate and extended vertically on the drain;
forming sources on laterally adjoining region to the drain of the silicon substrate;
forming gates at a predetermined depth of a vertically adjoining region to the source of the silicon substrate; and
forming word lines extending laterally on the gate,
wherein the gate fills associated one of grooves between two adjoining memory cells in a direction of bit line, a side wall between the two adjoining memory cells is simultaneously covered by an insulating film formed between the gate and the two memory cells, the gate is electrically connected to the two adjoining memory cells in a direction of bit line to allow two adjoining memory cells in a direction of bit line to share the gate connected to the one word line.

10. The method for fabricating the memory device according to claim 9, wherein the step of forming the drain comprises steps of:
forming grooves on a semiconductor substrate, which are arranged in a continuous manner as a diamond shape wherein lateral length is four times bit line width and vertical length is four times word line width;
forming a conductive film doped with impurities within the groove; and
performing a heat treatment process for the impurities to be diffused.

11. A method for fabricating the memory device according to claim 9, wherein the step of forming the gate comprises steps of:
forming a groove on a vertically adjoining region to the source of the silicon substrate;
forming a gate insulating film on an inside wall of the groove; and
filling the inside of the gate insulating film with conductive material.

12. A method for fabricating the memory device according to claim 9, further comprising step of:
forming capacitors on the source.

13. A method for fabricating a memory device on a silicon substrate comprising steps of:
forming drains at a predetermined depth of the silicon substrate in a continuous manner as a diamond shape;
forming bit lines which are buried within the silicon substrate and extended vertically on the drain;
forming sources on laterally adjoining region to the drain of the silicon substrate;
forming gates at a predetermined depth of a vertically adjoining region to the source of the silicon substrate; and
forming word lines extending laterally on the gate,
wherein the gate fills associated one of grooves between two adjoining memory cells in a direction of bit line, a side wall between the two adjoining memory cells is simultaneously covered by an insulating film formed between the gate and the two memory cells, and the gate is electrically connected to the two adjoining memory cells in a direction of bit line to allow two adjoining memory cells in a direction of bit line to share the gate connected to the one word line.

14. A method for fabricating the memory device according to claim 13, further comprising forming a contact portion between regions formed with two adjoining bit lines to each other among the regions formed with the bit lines on the silicon substrate.
